(19) United States
(12) Patent Application Publication
(10) Pub. No.: US 2019/0391654 A1
(43) Pub. Date: Dec. 26, 2019

(54) TACTILE SENSATION PROVIDING APPARATUS AND SIMULATION SYSTEM

(71) Applicant: FUJITSU LIMITED, Kawasaki-shi (JP)

(72) Inventors: KIYOSHI TANINAKA, Ebina (JP); Tsukasa Itani, Hadano (JP); Yasuhiro Endo, Ebina (JP)

(73) Assignee: FUJITSU LIMITED, Kawasaki-shi (JP)

(21) Appl. No.: 16/559,725

(22) Filed: Sep. 4, 2019

Related U.S. Application Data
(63) Continuation of application No. PCT/JP2017/015403, filed on Apr. 14, 2017.

(51) Int. Cl. G06F 3/01; B06B 1/04

(52) U.S. Cl. CPC G06F 3/016; H01L 41/09; B06B 1/045

(57) ABSTRACT

A tactile sensation providing apparatus includes: a housing; N (N is an integer equal to or greater than 2) vibrators attached to the housing, having resonance frequencies different from each other and configured to vibrate the housing; and a drive controller configured to simultaneously drive the N vibrators with N drive signals that vibrate the N respective vibrators in a resonance state, wherein the N drive signals cause the housing to generate reciprocating vibration by simultaneously driving the N respective vibrators, the reciprocating vibration having different speeds in a first direction and a second direction opposite to the first direction.

### CROSS-REFERENCE TO RELATED APPLICATION

This application is a continuation application of International Application PCT/JP2017/015403 filed on Apr. 14, 2017 and designated the U.S., the entire contents of which are incorporated herein by reference.

### FIELD

The embodiment discussed herein is related to a tactile sensation providing apparatus and a simulation system.

### BACKGROUND

A vibration generator is provided.

Japanese Laid-open Patent Publication No. 2012-148223 is disclosed as related art.

### SUMMARY

According to an aspect of the embodiments, a tactile sensation providing apparatus includes: a housing; N (N is an integer equal to or greater than 2) vibrators attached to the housing, having resonance frequencies different from each other and configured to vibrate the housing; and a drive controller configured to simultaneously drive the N vibrators with N drive signals that vibrate the N respective vibrators in a resonance state, wherein the N drive signals cause the housing to generate reciprocating vibration by simultaneously driving the N respective vibrators, the reciprocating vibration having different speeds in a first direction and a second direction opposite to the first direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an example diagram illustrating a tactile sensation providing apparatus according to an embodiment;

FIG. 2 is an example diagram illustrating the tactile sensation providing apparatus according to the embodiment;

FIGS. 3A and 3B are example diagrams illustrating ideal waveforms of acceleration oscillation to be generated in a housing;

FIG. 4 is an example diagram illustrating a sawtooth wave and waveforms obtained from equation (3);

FIG. 5 is an example diagram illustrating a simplified model for simulation of the tactile sensation providing apparatus;

FIG. 6 is an example diagram illustrating time changes of forces to be generated to act on permanent magnets of vibrators and the housing of the simplified model;

FIG. 7 is an example diagram illustrating simulation results of the simplified model;

FIG. 8 is an example diagram illustrating time changes of forces to be generated to act on the permanent magnets of the vibrators and the housing in the case where a phase difference between the forces is set to 0 in the simplified model;

FIG. 9 is an example diagram illustrating simulation results in the case where the phase difference between the forces is set to 0 in the simplified model;

FIG. 10 is an example diagram illustrating time changes of forces to be generated to act on the permanent magnet of one of the vibrators and the housing in the case of driving the one of the vibrators alone in the simplified model;

FIG. 11 is an example diagram illustrating simulation results in the case of driving the one of the vibrators alone in the simplified model;

FIG. 12 is another example diagram illustrating time changes of forces to be generated to act on the permanent magnet of the one of the vibrators and the housing in the case of driving the one of the vibrators alone in the simplified model;

FIG. 13 is another example diagram illustrating simulation results in the case of driving the one of the vibrators alone in the simplified model;

FIG. 14 is an example diagram illustrating an internal configuration of the tactile sensation providing apparatus;

FIG. 15 is an example diagram illustrating a simulation system according to the embodiment;

FIG. 16 is an example perspective view of a computer system to which a processing apparatus according to the embodiment is applied;

FIG. 17 is an example block diagram describing a configuration of main parts in a main body of the computer system;

FIG. 18 is an example diagram illustrating article data;

FIG. 19 is a diagram illustrating an example of images of articles;

FIG. 20 is an example diagram illustrating tabular data in which reaction forces have been associated with amplitude values;

FIG. 21 is an example flowchart illustrating a process to be performed by the processing apparatus according to the embodiment; and

FIG. 22 is an example flowchart illustrating a process to be performed when a drive controller of the tactile sensation providing apparatus drives the vibrators.

### DESCRIPTION OF EMBODIMENTS

For example, a vibration generator includes: a stator that includes a coil; a mover that includes a permanent magnet; an elastic body that connects the stator and the mover in such a way as to enable the mover to vibrate by using magnetic action of the permanent magnet and a magnetic field generated by the coil according to an input current to the coil; and a voltage input part that inputs, to the coil, a pulse voltage according to the natural period of the mover.

For example, the vibration generator vibrates a single mover (vibrator) in such a way as to generate asymmetric acceleration. In order to vibrate a single mover in such a way as to generate asymmetric acceleration, it is desirable to avoid causing the mover to be resonated. This involves vibrating the mover with a very large amplitude. For example, the vibration generator involves large power consumption in producing kinesthetic sense (tactile sensation) to be provided to a user. The vibration generator in the past is not efficient in this respect.

Thus, a tactile sensation providing apparatus and a simulation system capable of being driven efficiently may be provided.

The following describes an embodiment to which a tactile sensation providing apparatus and a simulation system according to the present embodiment have been applied.

### EMBODIMENT

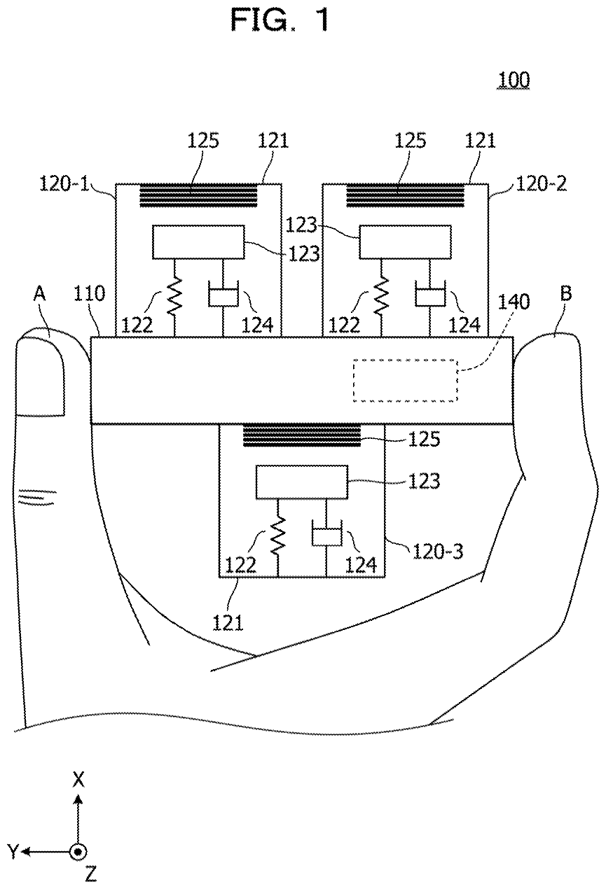

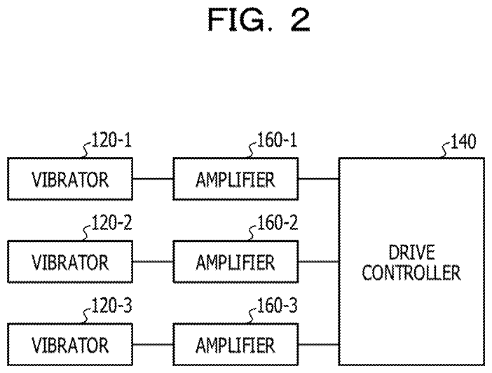

FIGS. 1 and 2 are example diagrams illustrating a tactile sensation providing apparatus 100 according to the embodiment. Description will be provided here by use of an XYZ coordinate system which is an example of a rectangular coordinate system.

The tactile sensation providing apparatus 100 includes a housing 110, vibrators 120-1, 120-2, and 120-3, and a drive controller 140. FIG. 1 illustrates the entire configuration of the tactile sensation providing apparatus 100. FIG. 2 illustrates the internal configuration of the vibrators 120-1, 120-2, and 120-3 and the drive controller 140.

The housing 110 is the housing of the tactile sensation providing apparatus 100, to be held by a hand of a user of the tactile sensation providing apparatus 100. The vibrators 120-1, 120-2, and 120-3 are fixed to the housing 110. As an example, FIG. 1 illustrates the following configuration: the housing 110 is a member made of resin or the like in a rectangular parallelepiped shape, and the vibrators 120-1, 120-2, and 120-3 are fixed to the outer surface of the housing 110. However, the vibrators 120-1, 120-2, and 120-3 may be provided inside the housing 110. Alternatively, some of the vibrators 120-1, 120-2, and 120-3 may be disposed inside the housing 110.

As an example, the mass of the housing 110 is approximately 10 to 100 times the mass of the vibrators 120-1, 120-2, and 120-3. The vibrators 120-1, 120-2, and 120-3 have respective specific resonance modes. As a result, when the vibrators 120-1, 120-2, and 120-3 are driven one by one, the housing 110 resonates while being nearly in resonance with each of the vibrators 120-1, 120-2, and 120-3. Therefore, when the vibrators 120-1, 120-2, and 120-3 are simultaneously vibrated at respective resonance frequencies, a vibration resulting from combination of the three resonances is generated in the housing 110.

The housing 110 is held by a thumb A and a forefinger B of the user. Thus, the user holds the tactile sensation providing apparatus 100 by holding a side surface of the housing 110 facing the Y-axis positive direction and a side surface thereof facing the Y-axis negative direction with tire thumb A and the forefinger B. Described here is a configuration in which both side surfaces of the housing 110 are held by the thumb A and the forefinger B. However, the user may hold the housing 110 with fingers other than the thumb A and the forefinger B. For example, both side surfaces of the housing 110 may be held with both palms.

The vibrators 120-1, 120-2, and 120-3 have configurations similar to each other. Accordingly, the configuration of the vibrator 120-1 will be described here. The vibrator 120-1 includes a housing 121, a spring 122, a permanent magnet 123, a damper 124, and an electromagnetic coil 125. The vibrators 120-1, 120-2, and 120-3 are driven in respective specific resonance states. The ratio of the resonance frequencies of the vibrators 120-1, 120-2, and 120-3 has been set to 1:2:3.

As an example, the housing 121 is a cylindrical hollow member made of metal or resin. The spring 122, the permanent magnet 123, the damper 124, and the electromagnetic coil 125 are disposed inside the housing 121.

The spring 122 has one end fixed to an inner wall of the housing 121 and the other end fixed to the permanent magnet 123. The end fixed to the inner wall of the housing 121 is a fixed end. The other end fixed to the permanent magnet 123 located on the opposite side is a free end.

The permanent magnet 123 is attached to the end (free end) of the spring 122. As an example, the south pole is located on the spring 122 side, and the north pole is located on a side opposite to the spring 122 (side closer to the electromagnetic coil 125).

The damper 124 is provided between the inner wall of the housing 121 and the permanent magnet 123, in parallel with the spring 122. Both ends of the damper 124 are respectively fixed to the inner wall of the housing 121 and the permanent magnet 123 to damp vibration of the spring 122. For example, it is possible to use an oil damper or a gas-filled damper as the damper 124.

When a current is supplied (turned on) by the drive controller (not illustrated), the electromagnetic coil 125 attracts the permanent magnet 123 in the X-axis positive direction. In this state, the spring 122 is stretched in the X-axis positive direction. In a state (off state) where no current is supplied to the electromagnetic coil 125, the permanent magnet 123 is pulled back in the X-axis negative direction by a contraction force of the spring 122. Therefore, it is possible to cause the permanent magnet 123 to reciprocate in the X-axis direction by intermittently supplying a current to the electromagnetic coil 125 at a predetermined frequency.

In order to drive the vibrators 120-1, 120-2 and 120-3 in the respective specific resonance states, spring constants of the springs 122 and the mass of the permanent magnets 123 are set to values that differ between the vibrators 120-1, 120-2 and 120-3.

As an example, the resonance frequencies of the vibrators 120-2 and 120-3 are set on the basis of the resonance frequency of the vibrator 120-1, as follows: the resonance frequency of the vibrator 120-2 is set to a value twice the resonance frequency of the vibrator 120-1, and the resonance frequency of the vibrator 120-3 is set to a value three times the resonance frequency of the vibrator 120-1. Therefore, the spring constants of the springs 122 and the mass of the permanent magnets 123 of the vibrators 120-1, 120-2, and 120-3 are set to respective values corresponding to the three resonance frequencies.

In addition, damping forces of the dampers 124 and/or magnetic forces to be generated by the electromagnetic coils 125 when a current flows may also differ between the vibrators 120-1, 120-2, and 120-3. This is to achieve a satisfactory tactile sensation.

The drive controller 140 is connected to the vibrators 120-1, 120-2, and 120-3 via amplifiers 160-1, 160-2, and 160-3. The drive controller 140 simultaneously drives the vibrators 120-1, 120-2, and 120-3 to cause the housing 110 to reciprocate in the X-axis direction.

The drive controller 140 simultaneously drives the vibrators 120-1, 120-2, and 120-3 with separate drive signals. The vibrators 120-1, 120-2, and 120-3 are driven in respective specific resonance states.

Next, described below is the principle of providing a tactile sensation to the user's fingertip by driving the vibrators 120-1, 120-2, and 120-3.

When human skin is subjected to a reciprocating vibration in a shear direction (a direction parallel to the skin surface), a Meissner's corpuscle of human skin receives a sense of being pulled in the forward direction if the speed of vibration in the forward direction is higher than the speed of vibration in the backward direction. If the speed of vibration in the backward direction is higher than the speed of vibration in the forward direction, the Meissner's corpuscle receives a sense of being pulled in the backward direction.

In the case where the vibrators 120-1, 120-2, and 120-3 are driven to reciprocate in the X-axis direction while the user is holding both side surfaces of the housing 110 with the thumb A and the forefinger B, the shear directions of the skin of the thumb A and the forefinger B correspond to the X-axis direction.

Then, assume the following driving pattern: when the vibrators 120-1, 120-2, and 120-3 are reciprocated in the X-axis direction, the vibrators 120-1, 120-2, and 120-3 are driven such that tire speed of vibration in the X-axis positive direction is higher than the speed of vibration in the X-axis negative direction. In the case of such a driving pattern, the user gets the sense that the thumb A and the forefinger B are pulled in the X-axis positive direction.

In contrast, assume the following driving pattern: when the vibrators 120-1, 120-2, and 120-3 are reciprocated in the X-axis direction, the vibrators 120-1, 120-2, and 120-3 are driven such that the speed of vibration in the X-axis negative direction is higher than the speed of vibration in the X-axis positive direction. In the case of such a driving pattern, the user gets the sense that the thumb A and the forefinger B are pulled in the X-axis negative direction.

The tactile sensation providing apparatus 100 provides the user with the sense that the thumb A and the forefinger B are pulled in the X-axis positive direction or in the X-axis negative direction, by simultaneously driving the vibrators 120-1, 120-2, and 120-3 with predetermined drive signals.

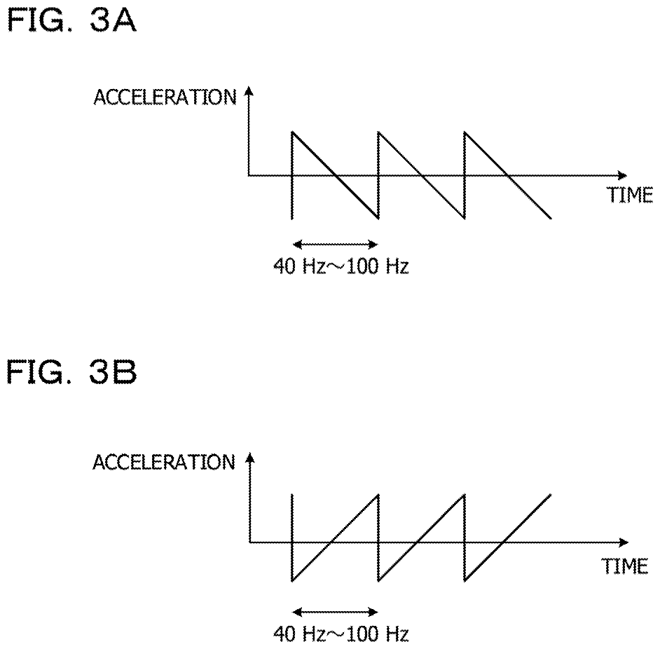

FIGS. 3A and 3B are example diagrams illustrating ideal waveforms of acceleration oscillation to be generated in the housing 110 so as to provide a sense of being pulled, FIGS. 3A and 3B illustrate acceleration oscillation patterns of the housing 110 with time on the horizontal axes and acceleration on the vertical axes. The two oscillation patterns illustrated in FIGS. 3A and 3B are each a sawtooth wave-like oscillation pattern in which the magnitude of the time rate of change of a rise in acceleration is different from the magnitude of the time rate of change of a fall in acceleration.

The rising behavior refers to a behavior of the acceleration of a sawtooth wave-like oscillation pattern, increasing from the minimum point to the maximum point. The falling behavior refers to a behavior of the acceleration of a sawtooth wave-like oscillation pattern, decreasing from the maximum point to the minimum point. At the time of rising, the acceleration applied to the housing 110 increases in the X-axis positive direction. At the time of falling, the acceleration applied to the housing 110 increases in the X-axis negative direction.

In the case of providing the thumb A and the forefinger B with a sense of being pulled in the X-axis positive direction, acceleration oscillation is generated in the housing 110 such that the speed of rise is higher than the speed of fall as illustrated in FIG. 3A. Meanwhile, in the case of providing the thumb A and the forefinger B with a sense of being pulled in the X-axis negative direction, acceleration oscillation is generated in the housing 110 such that the speed of fall is higher than the speed of rise as illustrated in FIG. 3B.

As an example, such a sense of being pulled is used as a tactile sensation indicating a reaction force to be generated when a pointer comes into contact with an article displayed on a screen in the case where the pointer displayed on the screen is operated by the tactile sensation providing apparatus 100 in a simulation system to be described later.

The two acceleration oscillation patterns illustrated in FIGS. 3A and 3B are merely examples. An oscillation pattern of any waveform may be applicable as long as the time rate of change of a rise in acceleration is different from the time rate of change of a fall in acceleration in the oscillation pattern. However, it is desirable that the frequency of the oscillation pattern be within a range of, for example, approximately 40 Hz to 100 Hz. This is because the sensitivity of a human muscle spindle is in this frequency band.

The acceleration oscillation pattern as described above is generated in the housing 110 in response to the motions of the drive controller 140, the vibrators 120-1, 120-2, and 120-3, and the housing 110. The acceleration oscillation pattern is not limited to a pattern of linear increase or decrease, but may be a pattern of nonlinear increase or decrease.

An oscillation pattern to be used as the acceleration oscillation pattern may be set as follows: acceleration at the time of rising of a waveform is made different from acceleration at the time of felling of a waveform such that the speed of upward movement of the housing 110 is different from the speed of downward movement of the housing 110.

The amplitude of the acceleration oscillation corresponds to the magnitude of the above-described tactile sensation indicating a reaction force. As the amplitude of the acceleration oscillation increases, the tactile sensation indicating a reaction force increases. As the amplitude of the acceleration oscillation decreases, the tactile sensation indicating a reaction force decreases.

For example, the amplitude of the acceleration oscillation is preferably set as follows. An experimenter compares a reaction force (1) with a reaction force (2). The reaction force (1) is a reaction force to be received by a hand pulling a spring. The reaction force (2) is a reaction force due to a sense of being pulled that is provided when the vibrators 120-1, 120-2, and 120-3 of the tactile sensation providing apparatus 100 are driven by drive signals of certain amplitudes (voltage values). A value of the reaction force (1) measured when the reaction force (1) equals the reaction force (2) is associated with amplitudes (voltage values) for generating the reaction force (2).

Such work is performed for the reaction force (1) of various magnitudes. As a result, tabular data are generated in which the measured values of the reaction force (1) are associated with the reaction force (2). The amplitudes of the drive signals are preferably set by use of such tabular data, according to the magnitude of the reaction force (2) to be provided to the hand of the user of the tactile sensation providing apparatus 100.

Next, described below are drive signals to be used when the drive controller 140 drives the vibrators 120-1, 120-2, and 120-3. As an example, of the vibrators 120-1, 120-2, and 120-3, the vibrator 120-1 is regarded as a reference vibrator.

The respective drive signals for driving the vibrators 120-1, 120-2, and 120-3 are regarded as voltage values represented by sine waves, and are represented by equation (1) below. Here, the letter “i” represents any value from 1 to 3. The letter “aᵢ” represents the amplitude of a drive signal. The letter “f” represents the resonance frequency of the vibrator 120-1. The letter “φᵢ” represents a predetermined phase included in a drive signal for driving an i-th vibrator among the vibrators 120-1, 120-2, and 120-3.

[Math 1]

Vᵢ=aᵢ sin[2π(if)t+{(i−1)π+φᵢ}] (1)

For example, equation (1) represents the drive signal for driving the i-th vibrator among the three vibrators 120-1, 120-2, and 120-3.

Therefore, the drive signal for the vibrator 120-1 is represented as a₁ sin(2πft+φᵢ). The drive signal for the vibrator 120-2 is represented as a₂ sin{2π(2f)t+(φ₂+π)}=−a₂ sin{2π(2f)t+φ₂}. The drive signal for the vibrator 120-3 is represented as a₃ sin{2π(3f)t+(φ₃+2π)}=a₃ sin{2π(3f)t+φ₃}.

The coefficient aᵢ of amplitude and the phase φᵢ are numerical values to be used for making adjustment such that an acceleration represented by equation (2) below is generated to act on the housing 110 as a result of inputting a drive signal represented by equation (1) to the i-th vibrator.

$$[ Math 2 ]$$

$${y}_{i} = \frac{{A}_{1}}{i} sin [ 2 π ( if ) t + ( i - 1 ) π ] \qquad ( 2 )$$

The letter “A₁” represents an acceleration amplitude to be generated as a result of the amplitude a₁ of a drive signal for a first vibrator and dynamic characteristics of the tactile sensation providing apparatus 100. The acceleration amplitude A₁ is related to the magnitude of tactile sensation.

Accelerations (1′) to be generated, by these three drive signals, to act on the housing are combined to give equation (3) below.

$$[ Math 3 ]$$

$$y = {A}_{1} [ sin ( 2 π ft ) - \frac{1}{2} sin \{ 2 π ( 2 f ) t \} + \frac{1}{3} sin \{ 2 π ( 3 f ) t \} ] \qquad ( 3 )$$

Equation (3) corresponds to an equation obtained as a result of multiplying, by a constant, the sum of the first to third terms of a numerical expression derived from the Fourier series expansion of the sawtooth wave illustrated in FIG. 3B. The numerical expression derived from the Fourier series expansion of the sawtooth wave is represented by equation (4). Equation (4) includes the first to N-th term.

$$[ Math 4 ]$$

$$y = \frac{2}{π} [ sin 2 π ft - \frac{1}{2} sin \{ 2 π ( 2 f ) t \} + \frac{1}{3} sin \{ 2 π ( 3 f ) t \} - ⋯ + \frac{1}{3} sin \{ 2 π ( Nf ) t \} ] \qquad ( 4 )$$

The resonance frequencies of the vibrators 120-1, 120-2, and 120-3 are different from each other as described above. Assume that a system having mass, a spring, and damping, as the vibrator 120, is connected to the housing 110, and that an acceleration of a sine wave is given to the mass of the vibrator. Then, an acceleration of a sine wave different from the above-described sine wave in amplitude and phase is generated to act on the housing. The amplitude aᵢ and the phase φᵢ of equation (1) are provided so as to adjust such drive vibration such that a relationship between the amplitude and the phase of vibration generated in the housing 110 satisfies equation (3). It is possible to set the predetermined amplitude aᵢ and phase φᵢ to optimum values in a simulation, experiment, and/or the like according to the mass of the housing 110 and the mass, spring constants, and the like of the vibrators 120-1, 120-2, and 120-3.

Data representing the amplitudes aᵢ, the frequencies if, and the phases φᵢ of drive signals are preferably stored in an internal memory or the like of the drive controller 140. This enables the drive controller 140 to read the amplitude aᵢ, the frequency if, and the phase φᵢ from the internal memory or the like when generating a drive signal.

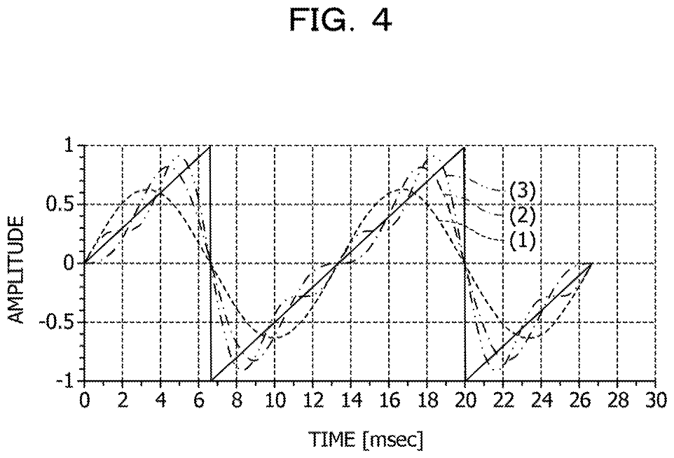

FIG. 4 is an example diagram illustrating a sawtooth wave and waveforms obtained from equation (3). In FIG. 4, the horizontal axis represents time, and the vertical axis represents acceleration amplitude. FIG. 4 illustrates waveforms (1) to (3) as the waveforms obtained from equation (3). The waveform (1) is obtained from the first term of equation (3) alone, and is indicated by a broken line. The waveform (2) is a waveform resulting from combining the first and second terms of equation (3), and is indicated by a dashed-dotted line. The waveform (3) is a waveform resulting from combining the first to third terms of equation (3), and is indicated by a two-dot chain line. In addition, a sawtooth wave is indicated by a solid line.

As illustrated in FIG. 4, the waveform (1) is a sine wave. Meanwhile, as with the sawtooth wave, the waveforms (2) and (3) depict patterns in which the time rate of change of a fall in acceleration is higher than the time rate of change of a rise in acceleration. Additionally, in terms of shape, the waveform (3) is closer to the sawtooth wave than the waveform (2) is.

The waveform (2) resulting from combining the first and second terms and the waveform (3) resulting from combining the first to third terms are illustrated here for convenience of description. Acceleration oscillation represented by the waveform (2) is considered to be caused in the housing 110 if the vibrators 120-1 and 120-2 are simultaneously driven. Acceleration oscillation represented by the waveform (3) is considered to be caused in the housing 110 if the vibrators 120-1, 120-2 and 120-3 are simultaneously driven.

It is considered that if N is set to a value equal to or greater than 4 in equation (4), it is possible to obtain a waveform much closer, in terms of shape, to the sawtooth wave than the waveform (3) is.

Therefore, it is considered that when a plurality of the vibrators is simultaneously driven by drive signals having different values of i and satisfying conditions for equations (1) and (2), it is possible to generate, at the housing 110, an acceleration waveform that closely resembles the sawtooth wave.

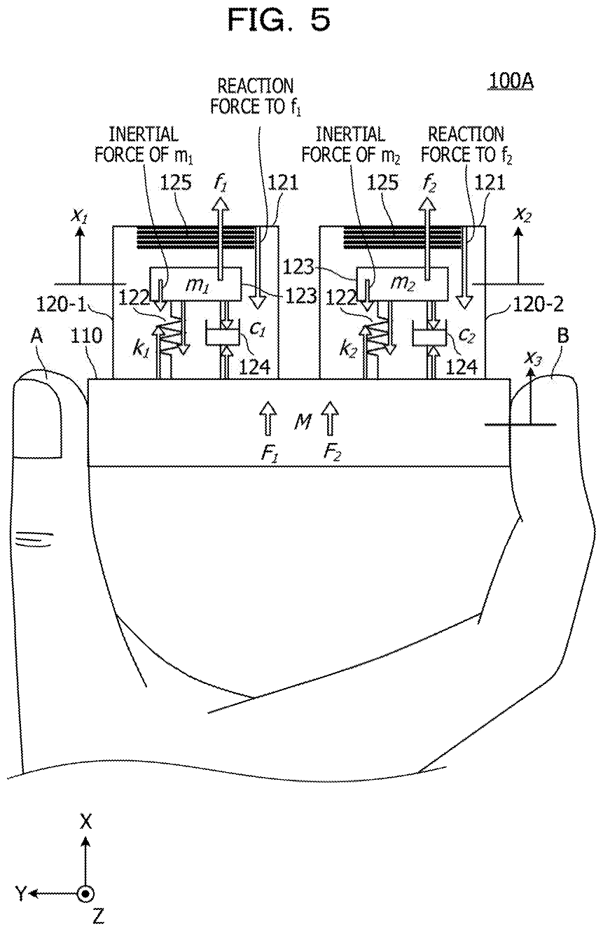

FIG. 5 is an example diagram illustrating a simplified model 100A for simulation of the tactile sensation providing apparatus 100. The simplified model 100A includes the housing 110 and the vibrators 120-1 and 120-2. The simplified model 100A includes the two vibrators 120-1 and 120-2, but does not include the vibrator 120-3.

Here, let k₁ and k₂ be the spring constants of the springs 122 of the vibrators 120-1 and 120-2, m₁ and m₂ be the mass of the permanent magnets 123 of the vibrators 120-1 and 120-2, and C₁ and C₂ be the damping coefficients of the dampers 124 of the vibrators 120-1 and 120-2, respectively. In addition, let x₁ and x₂ be displacements of the permanent magnets 123 of the vibrators 120-1 and 120-2, respectively, and x₃ be a displacement of the housing 110. The positive directions of the displacements x₁, x₂, and x₃ correspond to the X-axis positive direction. Let v₁, v₂, and v₃ be velocities resulting from differentiating the displacements x₁, x₂, and x₃ with respect to time, respectively. Furthermore, let f₁ and f₂ be forces to be generated to act on the permanent magnets 123 by electromagnetic forces from the coils. The positive directions of the forces f₁ and f₂ correspond to the X-axis positive direction, as indicated by arrows. When the permanent magnets 123 vibrate due to f₁ and f₂, spring forces of k₁(x₁−x₃) and k₂(x₂−x₃) are generated to act on the springs, and damping forces of c₁(x′₁−x′₃) and c₂(x′₂−x′₃) and inertial forces of m₁x″₁ and m₂x″₂ are generated to act on the dampers. As resultant forces of these forces, resultant forces F1 and F2 are generated to act on the housing 110.

In the simplified model 100A as described above, the potential energy of the springs 122 of the vibrators 120-1 and 120-2 is represented by equation (5) below.

[Math 5]

U=½k₁(x₁−x₃)²+½k₂(x₂−x₃)² (5)

The kinetic energy of the permanent magnets 123 of the vibrators 120-1 and 120-2 is represented by equation (6) below.

[Math 6]

T=½m₁v₁²+½m₂v₂²+½Mv₃² (6)

In addition, energy to be lost by the dampers 124 of the vibrators 120-1 and 120-2 is represented by equation (7) below.

It is relatively complicated to derive the equation of motion of the simplified model 100A. Therefore, it is preferable that the Lagrange method be applied to energy equations (5) and (6) in accordance with the common practice.

[Math 7]

U=½c₁(v₁−v₃)²+½c₂(v₂−v₃)² (7)

The values of the acceleration, velocity, and displacement of the housing 110 have been sought in the case where the vibrators 120-1 and 120-2 are driven by use of the equation of motion of the simplified model 100A derived in this manner. Then, the following results have been obtained.

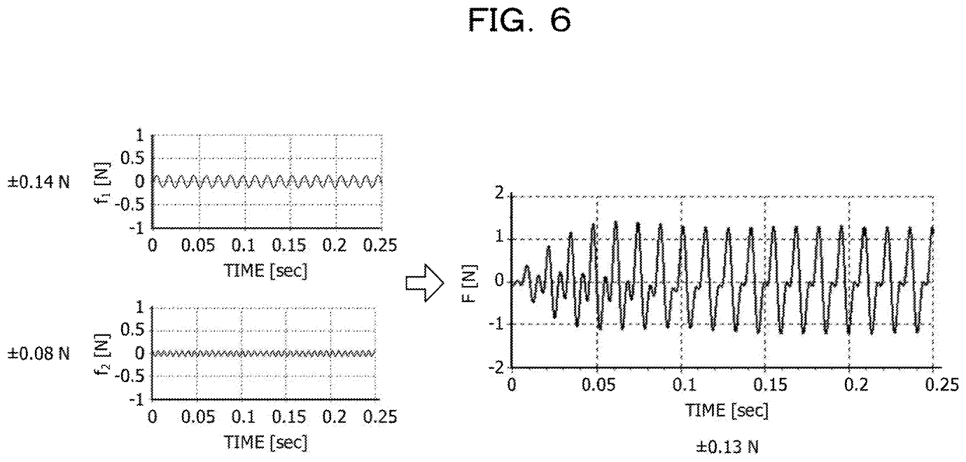

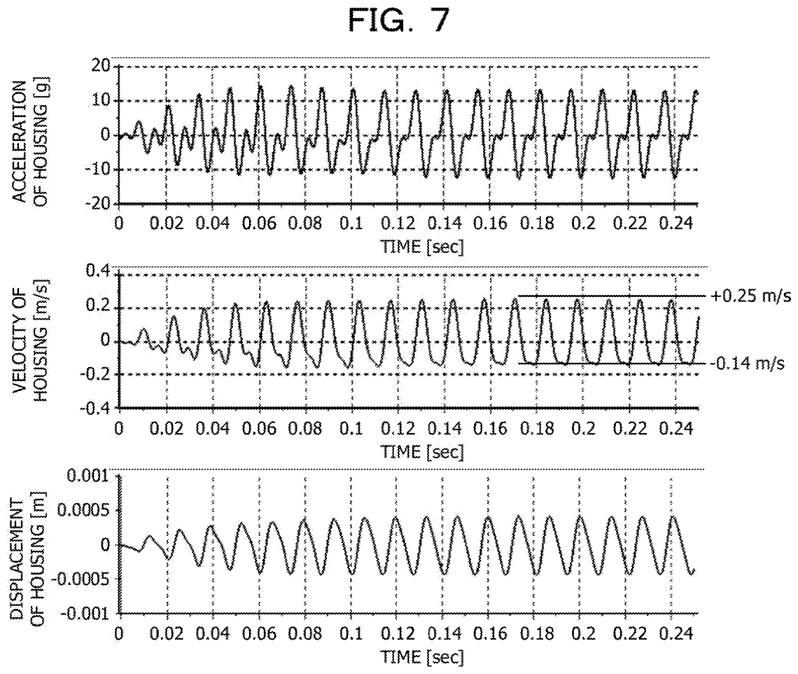

FIG. 6 is an example diagram illustrating time changes of the forces f₁ and f₂ to be generated to act on the permanent magnets 123 of the vibrators 120-1 and 120-2 of the simplified model 100A. FIG. 7 is an example diagram illustrating simulation results of the simplified model 100A.

The vibrators 120-1 and 120-2 have been driven such that the forces f₁ and f₂ illustrated on the left of FIG. 6 are generated to act on the mass 123 of the vibrators 120-1 and 120-2. The forces f₁ and f₂ have amplitudes of ±0.14 (N) and ±0.08 (N), respectively. The phase of the force f₂ is delayed by π/2 with respect to the force f₁.

As a result of thus driving the vibrators 120-1 and 120-2, a force F illustrated on the right of FIG. 6 has been generated to act on the housing 110. The force F is the resultant force of the forces F₁ and F₂ generated as a result of motions of the vibrators 120-1 and 120-2, respectively. That is, F=F₁+F₂. The force F has characteristics of different waveforms for vibration in the positive direction and vibration in the negative direction.

As with the force F, the acceleration of the housing 110 has characteristics of different waveforms for vibration in the positive direction and vibration in the negative direction, as illustrated in FIG. 7. The speed of the housing 110 is +0.25 m/s on the positive side and −14 m/s on the negative side. Thus, the housing 110 has characteristics of different speeds for vibration in the positive direction and vibration in the negative direction. With regard to displacement, the amplitude of vibration in the positive direction is substantially equal to that of vibration in the negative direction.

As a result, the following has been confirmed. As described above, the speed of the housing 110 differs between vibration in the positive direction and vibration in the negative direction. Accordingly, it is possible to cause a shear deformation on the surfaces of the thumb A and the forefinger B of the user with different speeds in the forward direction and the backward direction, and thus possible to provide a tactile sensation.

Next, described below for comparison are simulation results in the case where a phase difference between the forces f₁ and f₂ is set to 0.

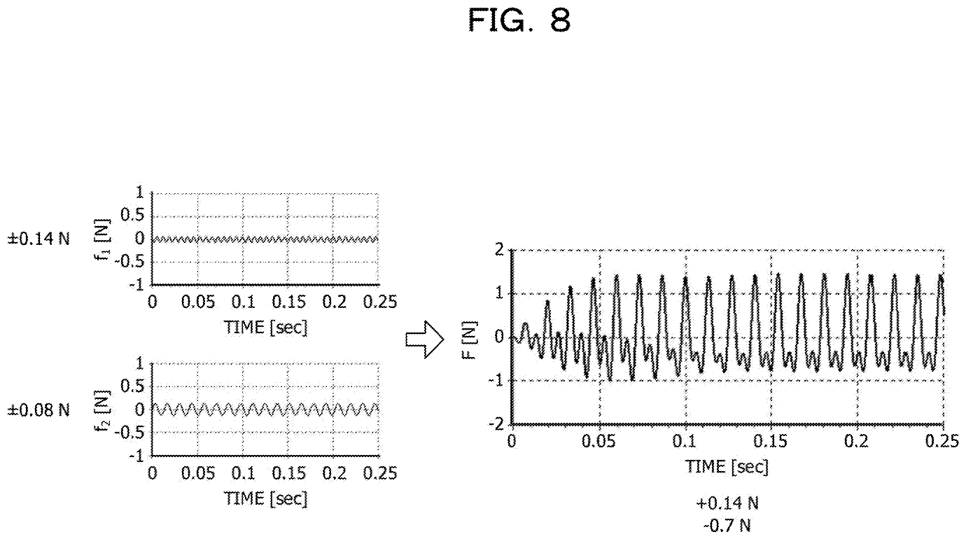

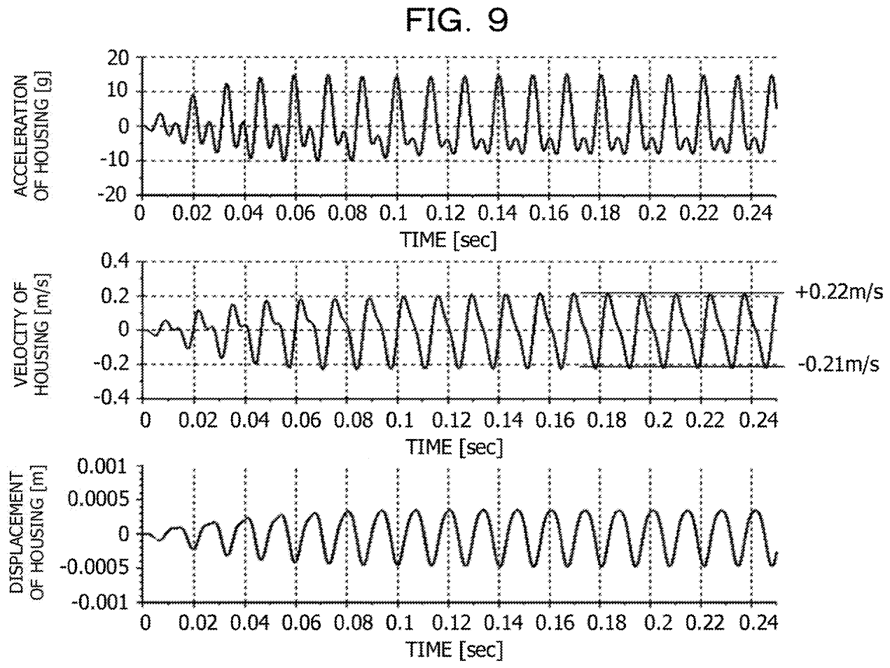

FIG. 8 is an example diagram illustrating time changes of the forces f₁ and f₂ to be generated to act on the mass 123 of the vibrators 120-1 and 120-2 in the case where the phase difference between the forces f₁ and f₂ is set to 0 in the simplified model 100A. FIG. 9 is an example diagram illustrating simulation results in the case where the phase difference between the forces f₁ and f₂ is set to 0 in the simplified model 100A.

As illustrated on the left of FIG. 8, tire amplitudes of the forces f₁ and f₂ are ±0.14 (N) and 0.08 (N), respectively, and the phase difference between the forces f₁ and f₂ is 0.

As a result of driving the vibrators 120-1 and 120-2 after setting the phase difference between the forces f₁ and f₂ to 0 as described above, the force F illustrated on the right of FIG. 8 has been generated to act on the housing 110. As Illustrated in FIG. 9, the acceleration of the housing 110 has characteristics similar to those of the force F. The speed of the housing 110 is +0.22 m/s on the positive side and −0.21 m/s on the negative side. Thus, the speed of the housing 110 vibrating in the positive direction is substantially equal to the speed of the housing 110 vibrating in the negative direction. With regard to displacement, the amplitude of vibration in the positive direction is substantially equal to that of vibration in the negative direction.

As a result, the following has been confirmed. As described above, the speed of the housing 110 vibrating in the positive direction is substantially equal to the speed of the housing 110 vibrating in the negative direction. Thus, in the case where the phase difference between the forces f₁ and f₂ is set to 0, it is not possible to cause a shear deformation on the surfaces of the thumb A and the forefinger B of the user with different speeds in the forward direction and the backward direction, and not possible to provide a tactile sensation accordingly.

Next, a simulation has been performed in the simplified model 100A for comparison under the following conditions: the vibrator 120-1 is driven, the vibrator 120-2 is not driven, the vibrator 120-1 is not resonated, and acceleration differs between vibration in the positive direction and vibration in the negative direction. Here, acceleration is changed in a sawtooth wave-like manner so as to satisfy the condition that acceleration differs between vibration in the positive direction and vibration in the negative direction.

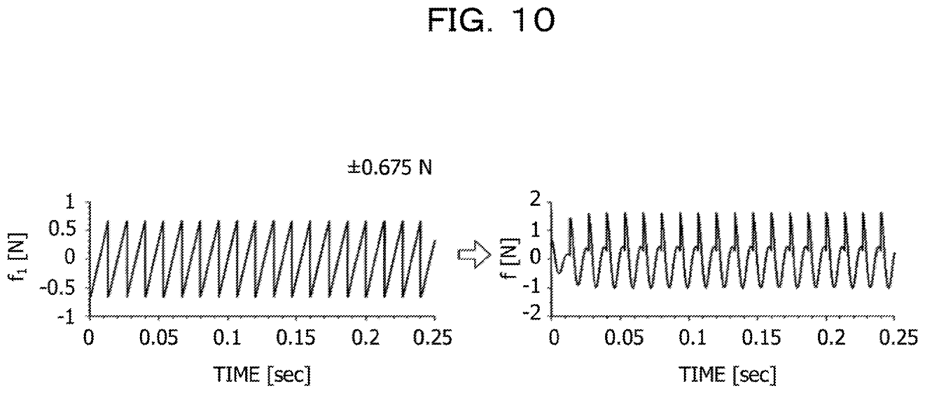

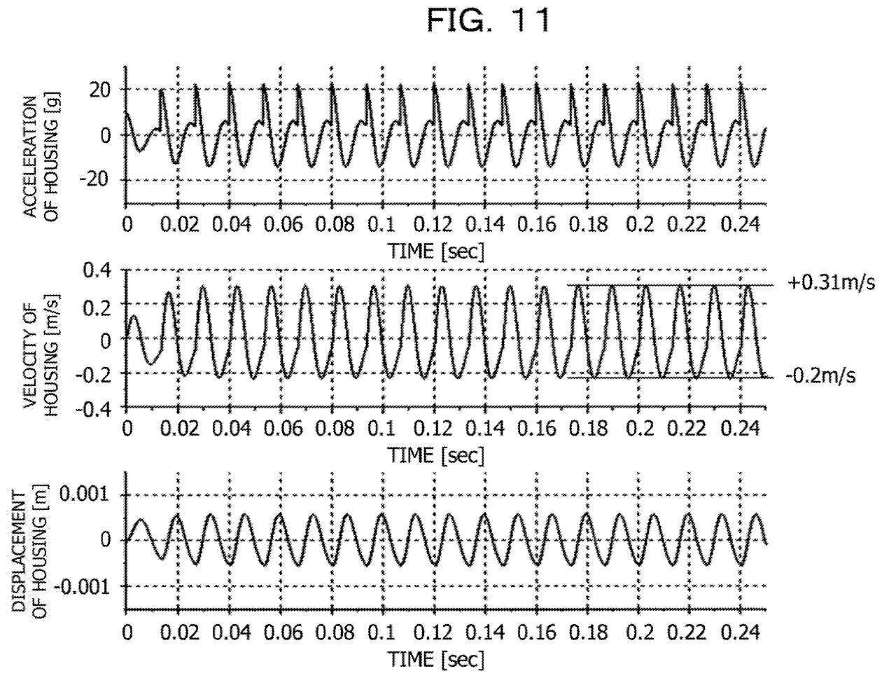

FIG. 10 is an example diagram illustrating time changes of the force f₁ to be generated to act on the mass 123 of the vibrator 120-1 and the force F to be generated to act on the housing 110 in the case of driving the vibrator 120-1 alone in the simplified model 100A. As illustrated in FIG. 10, acceleration to be generated to act on the vibrator 120-1 is changed in a sawtooth wave-like manner. FIG. 11 is an example diagram illustrating simulation results in the case of driving the vibrator 120-1 alone in the simplified model 100A.

The spring constant k₁ has been changed so as not to cause the vibrator 120-1 to be resonated by a drive signal of 40 to 100 Hz suitable for generating a tactile sensation. The amplitude of the force ft has been set to 0.675 (N) as illustrated on the left of FIG. 10. This corresponds to a value equal to or more than four times the force ft to be generated in the case of resonating the vibrator 120-1 as illustrated in FIG. 6.

As a result of thus driving the vibrator 120-1 alone, the force F illustrated on the right of FIG. 10 has been generated to act on the housing 110. As Illustrated in FIG. 11, the acceleration of the housing 110 has characteristics similar to those of the force F. The speed of the housing 110 is +0.31 m/s on the positive side and −0.23 m/s on the negative side. Thus, the housing 110 has characteristics of different speeds for vibration in the positive direction and vibration in the negative direction. With regard to displacement, the amplitude of vibration in the positive direction is substantially equal to that of vibration in the negative direction.

As a result, the following has been confirmed. As described above, the speed of the housing 110 differs between vibration in the positive direction and vibration in the negative direction. Accordingly, it is possible to cause a shear deformation on the surfaces of the thumb A and the forefinger B of the user with different speeds in the forward direction and the backward direction, and thus possible to provide a tactile sensation.

However, driving the vibrator 120-1 without causing resonance increases power consumption of the vibrator 120-1. Therefore, it is not possible to efficiently provide a tactile sensation.

Next, a simulation has been performed for comparison under the following conditions: the vibrator 120-1 illustrated in FIG. 5 is resonated, and an acceleration to be generated to act on the vibrator 120-1 is reduced to 1/10.

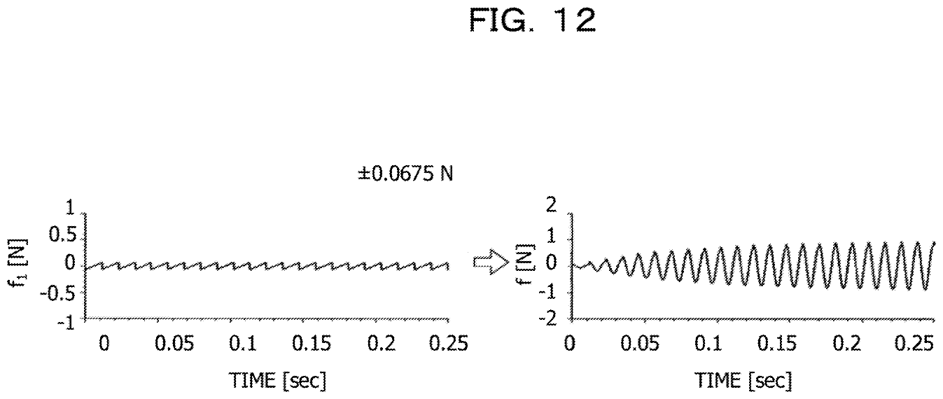

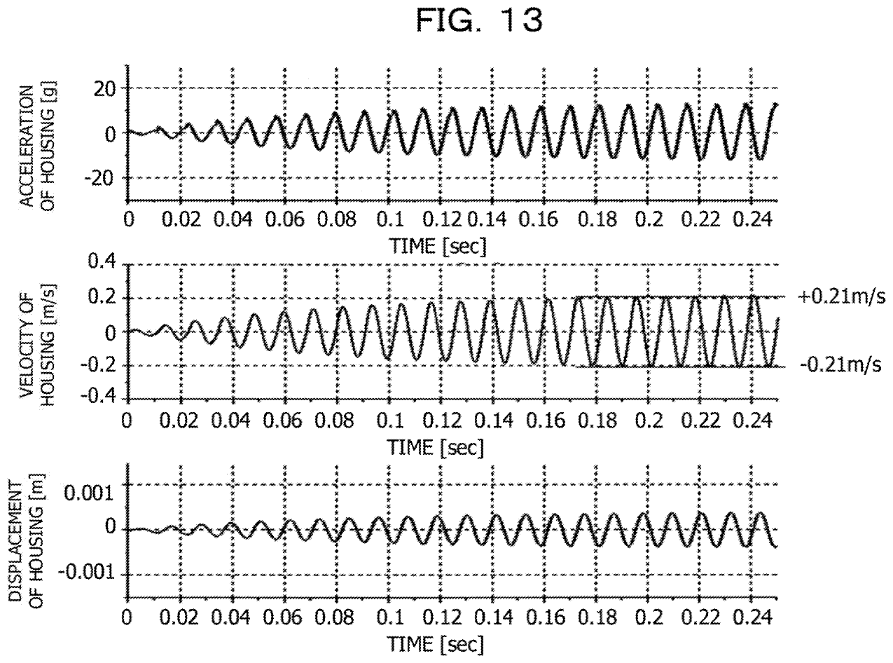

FIG. 12 is another example diagram illustrating time changes of the force f₁ to be generated to act on the mass of the vibrator 120-1 and the force F to be generated to act on the housing 110 in the case of driving the vibrator 120-1 alone in the simplified model 100A, FIG. 13 is another example diagram illustrating simulation results in the case of driving the vibrator 120-1 alone in the simplified model 100A.

As Illustrated on the left of FIG. 12, the amplitude of the force f1 has been set to 0.0675 (N). This corresponds to 1/10 of the force f₁ illustrated in FIG. 10.

As a result of thus driving the vibrator 120-1 alone in a resonance state, the force F illustrated on the right of FIG. 12 has been generated to act on the housing 110. As illustrated in FIG. 13, the acceleration of the housing 110 has characteristics similar to those of the force F. The speed of the housing 110 is +0.21 m/s on the positive side and −0.21 m/s on the negative side. Thus, the speed of the housing 110 vibrating in the positive direction is substantially equal to the speed of the housing 110 vibrating in the negative direction. With regard to displacement, the amplitude of vibration in the positive direction is substantially equal to that of vibration in the negative direction.

In the case of thus driving the vibrator 120-1 alone in a resonance state in a sawtooth wave-like pattern, the speed of the housing 110 vibrating in the positive direction equals the speed of the housing 110 vibrating in the negative direction.

In this case, it is not possible to cause a shear deformation on the surfaces of the thumb A and the forefinger B of the user with different speeds in the forward direction and the backward direction, and not possible to provide a tactile sensation accordingly. It has been found that in the case of thus driving the vibrator 120-1 in a sawtooth wave-like manner without causing resonance, it is not possible to provide a tactile sensation unless a relatively large force is generated by the vibrator 120-1. In the case of attempting to provide a tactile sensation by use of the single vibrator 120-1, power consumption of the vibrator 120-1 increases as described with reference to FIGS. 10 and 11. Therefore, it is not possible to efficiently provide a tactile sensation.

Thus, using resonance of a vibrator so as to reduce power consumption of the vibrator involves the simultaneous driving of a plurality of vibrators having different resonance frequencies with acceleration oscillation represented by the Fourier series expansion of an acceleration waveform. The Fourier series expansion of an acceleration waveform is known for creating a sensory illusion such as a sawtooth wave. Furthermore, achieving such an acceleration oscillation involves use of drive signals with a predetermined amplitude ratio and phase difference.

As described above, according to the embodiment, the three vibrators 120-1, 120-2, and 120-3 having resonance frequencies different from each other are simultaneously driven by drive signals represented by three terms of the Fourier series expansion of a sawtooth wave. As a result, the speed of the housing 110 vibrating in the positive direction differs from the speed of the housing 110 vibrating in the negative direction. It is thus possible to cause a shear deformation on the surfaces of the thumb A and the forefinger B of the user with different speeds in the forward direction and the backward direction.

Vibration of the housing 110 for generating such a shear deformation is achieved by the three vibrators 120-1, 120-2, and 120-3 being simultaneously resonated. For example, it is possible to achieve a large amplitude of vibration of the housing 110 with low power consumption.

Therefore, it is possible to provide the tactile sensation providing apparatus 100 capable of being driven efficiently.

The tactile sensation providing apparatus 100 and the simplified model 100A have been described above. The tactile sensation providing apparatus 100 includes the three vibrators 120-1, 120-2, and 120-3. The simplified model 100A includes the two vibrators 120-1 and 120-2. However, the number of vibrators is not limited as long as there are inducted N vibrators having resonance frequencies different from each other and the housing 110 is driven by an acceleration represented by N terms of the Fourier series expansion of a sawtooth wave. Note that the N terms of the Fourier series of sine waves refer to N consecutive terms starting from the first term.

A configuration has been described above in which N vibrators are driven by use of accelerations corresponding to N terms of the Fourier series expansion of a sawtooth wave. However, the acceleration may be of any waveform other than a sawtooth wave. The acceleration to be generated by the N vibrators may be in any form other than the Fourier series expansion of a sawtooth wave as long as it is possible to cause the housing 110 to vibrate at different speeds in the positive direction and the negative direction, by driving the N vibrators having resonance frequencies different from each other.

A configuration has been described above in which drive signals for the N vibrators are optimized through a simulation. Meanwhile, the amplitude and phase of the drive signal for each of the N vibrators may be determined in such a way as to maximize the amplitude of vibration of the housing 110 in a manner similar to solving an optimization problem, with the amplitude and phase of the drive signal for each vibrator as parameters. In such a case, an accelerometer is preferably attached to the housing 110 so as to measure a vibration of the housing 110. It is preferable to use, for example, a small and lightweight accelerometer implemented based on Micro Electro Mechanical Systems (MEMS). Such an accelerometer outputs vibration representing a change in capacitance caused when acceleration is applied.

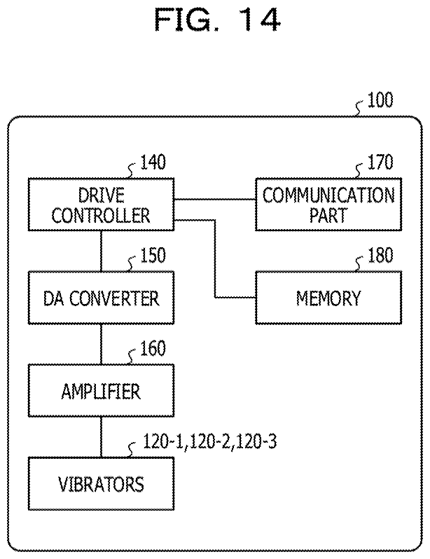

Finally, a simulation system including the tactile sensation providing apparatus 100 will be described with reference to FIGS. 14 to 22.

FIG. 14 is an example diagram illustrating an internal configuration of the tactile sensation providing apparatus 100.

The tactile sensation providing apparatus 100 includes the vibrators 120-1, 120-2, and 120-3, the drive controller 140, a DA converter 150, an amplifier 160, a communication part 170, and a memory 180. The communication part 170 will be mainly described here. The amplifiers 160-1, 160-2, and 160-3 illustrated in FIG. 2 are collectively referred to as the amplifier 160.

For example, the communication part 170 performs wireless communication with a processing apparatus in the simulation system according to a standard such as Bluetooth (registered trademark) or wireless fidelity (WiFi). The communication part 170 is connected to the drive controller 140, and outputs a drive command to the drive controller 140 when receiving the drive command from the processing apparatus in the simulation system. As a result the drive controller 140 drives the vibrator 120-1, 120-2, or 120-3 or any combination thereof. A vibrator to be driven out of the vibrators 120-1, 120-2, and 120-3 and an amplitude and a phase with which the vibrator is to be driven are determined by the phase and the magnitude of components in the X-axis, Y-axis, and Z-axis directions of an acceleration to be generated to act on the housing 110. A relationship between a drive signal and the amplitude and phase of an acceleration to be generated to act on the housing 110 is preferably determined by use of a common frequency transfer (Unction identification method.

The memory 180 stores data as the source of drive signals to be generated by the drive controller 140. In the case where drive signals are sinusoidal signals, the memory 180 stores data representing sine waves. The frequencies of sine waves and the amplitude and phase difference for each vibrator have been determined in toe data representing sine waves. Thus, when the drive controller 140 sets an amplitude, it is possible to generate a drive signal as illustrated in FIG. 6.

When receiving data representing an amplitude and a phase from the processing apparatus in the simulation system to be described later, toe drive controller 140 generates a sinusoidal drive signal specified by the amplitude and the phase. The values of toe amplitude and the phase are determined by a transfer function between the drive signal and the acceleration to be generated to act on the housing 110 as described above.

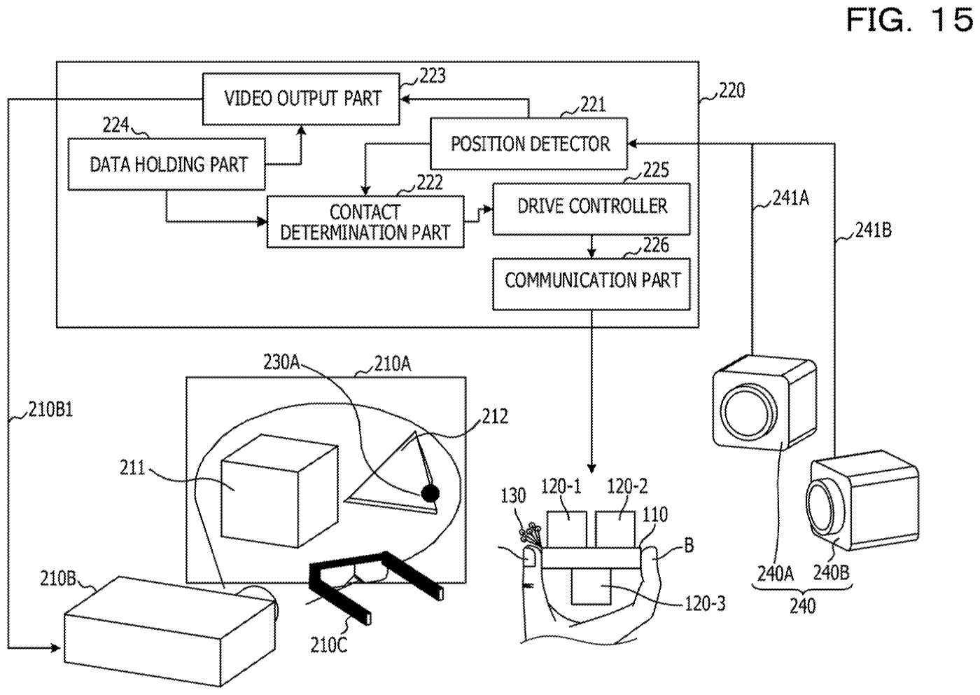

FIG. 15 is an example diagram illustrating a simulation system 200 according to the embodiment.

The simulation system 200 includes the tactile sensation providing apparatus 100, a screen 210A, a projection apparatus 2108, three-dimensional (3D) glasses 210C, a processing apparatus 220, and a position measurement apparatus 240.

It is possible to apply the simulation system 200 to, for example, an assembly support system for grasping assembly workability in a virtual space. The assembly support system enables simulation of the work of assembling electronic components on a motherboard or the like in a virtual space. Examples of the electronic components include a central processing unit (CPU) module, a memory module, a communication module, and a connector.

However, the simulation system 200 is not limited to the assembly support system. It is also possible to apply the simulation system 200 to various systems for checking workability in the three-dimensional space.

A marker 130 is attached to the housing 110. The marker 130 includes a plurality of spheres, and reflects infrared rays in various directions when being irradiated with the infrared rays in toe simulation system to be described later. The marker 130 is used by the processing apparatus in the simulation system, for detecting the position of the tactile sensation providing apparatus 100.

For example, it is possible to use a projector screen as the screen 210A. The size of the screen 210A may be set as appropriate, depending on the purpose. The screen 210A displays an image projected by the projection apparatus 210B. Here, it is assumed that images of articles 211 and 212 are displayed on the screen 210A.

Any apparatus may be used as the projection apparatus 210B as long as the apparatus is capable of projecting an image on the screen 210A. For example, it is possible to use a projector as the projection apparatus 210B. The projection apparatus 210B is connected to the processing apparatus 220 by a cable 210B1, and projects an image input from the processing apparatus 220 onto the screen 210A. Here, the projection apparatus 210B is assumed to be of a type capable of projecting a 3D image (stereoscopic image) onto the screen 210A.

The screen 210A and the projection apparatus 210B are each an example of a display part.

The 3D glasses 210C are to be worn by a user of the simulation system 200. The 3D glasses 210C may be any glasses capable of converting, into a 3D image, an image projected on the screen 210A by die projection apparatus 210B. For example, it is possible to use, as the 3D glasses 210C, polarized glasses for polarizing incident light or liquid crystal shutter glasses including a liquid crystal shutter.

For example, a liquid crystal display panel may be used instead of the screen 210A and the projection apparatus 210B. If the 3D glasses 210C are unnecessary, there is no need to use the 3D glasses 210C. In addition, a head-mounted display may be used instead of the screen 210A and the projection apparatus 210B.

The processing apparatus 220 includes a position detector 221, a contact determination part 222, a video output part 223, a data holding part 224, a drive controller 225, and a communication part 226. Tire processing apparatus 220 is implemented by, for example, a computer including a memory.

The position detector 221 performs image processing such as pattern matching on image data input from the position measurement apparatus 240, to detect the position and orientation of the marker 130 of the tactile sensation providing apparatus 100. The position of the tactile sensation providing apparatus 100 is represented by coordinate values in a three-dimensional coordinate system. The orientation thereof is represented by angles with respect to directions of the three axes of the three-dimensional coordinate system.

The position detector 221 converts the coordinate values in the three-dimensional coordinate system into coordinates in an image to be projected on the screen 210A, and outputs the coordinates as coordinates representing the position of a pointer 230A. The position detector 221 is an example of a second detector. For example, the position of the pointer 230A is determined by the position of the tactile sensation providing apparatus 100. It is possible to move the pointer 230A projected on the screen 210A simply by moving the tactile sensation providing apparatus 100 in the real space. The tactile sensation providing apparatus 100 may be regarded as an operation terminal of the pointer 230A.

The position and orientation of the tactile sensation providing apparatus 100 may be detected by the position measurement apparatus 240.

The contact determination part 222 determines whether the pointer 230A displayed on the screen 210A has come into contact with an image of the article 211 or 212 projected on the screen 210A.

The contact determination part 222 determines whether the pointer 230A has come into contact with the image of the article 211 or 212, by using data representing the shape and position of the article 211 or 212 projected on the screen 210A and data representing the position of the pointer 230A. The contact determination part 222 is an example of a determination part.

An output terminal of the video output part 223 is connected to the projection apparatus 210B by the cable 210B1. The video output part 223 outputs, to the projection apparatus 210B, images specified by article data of the articles 211 and 212 held by the data holding part 224, and causes the projection apparatus 210B to display the images on the screen 210A.

The video output part 223 causes the projection apparatus 210B to display the pointer 230A. The position of the pointer 230A in an image displayed on the screen 210A is determined by the position and orientation of the tactile sensation providing apparatus 100 detected by the position detector 221.

The data holding part 224 holds data such as article data representing the coordinates and shapes of the articles 211 and 212 and image data of the pointer 230A. The data holding part 224 is an example of a data storage part, and is implemented by a memory.

When the contact determination part 222 determines that the pointer 230A has come into contact with the image of the article 211 or 212, the drive controller 225 outputs a drive signal of a vibration pattern representing a reaction force, according to a direction in which the pointer 230A has come into contact with the article 211 or 212. The drive signal is a signal for driving the vibrator of the tactile sensation providing apparatus 100.

The communication part 226 is a communication part that performs wireless communication with the tactile sensation providing apparatus 100. For example, the communication part 226 is capable of performing wireless communication according to a standard such as Bluetooth or WiFi. The communication part 226 transmits a drive signal generated by the drive controller 225 to the tactile sensation providing apparatus 100. The communication part 226 may be a communication part that performs wired communication with the tactile sensation providing apparatus 100.

The position measurement apparatus 240 includes infrared cameras 240A and 240B connected to the position detector 221 by cables 241A and 241B, respectively. The infrared cameras 240A and 240B irradiate the tactile sensation providing apparatus 100 with infrared rays, and capture images of reflected light from the marker 130. The position measurement apparatus 240 transfers, to the position detector 221, image data output from the infrared cameras 240A and 240B. The position measurement apparatus 240 is an example of a first detector.

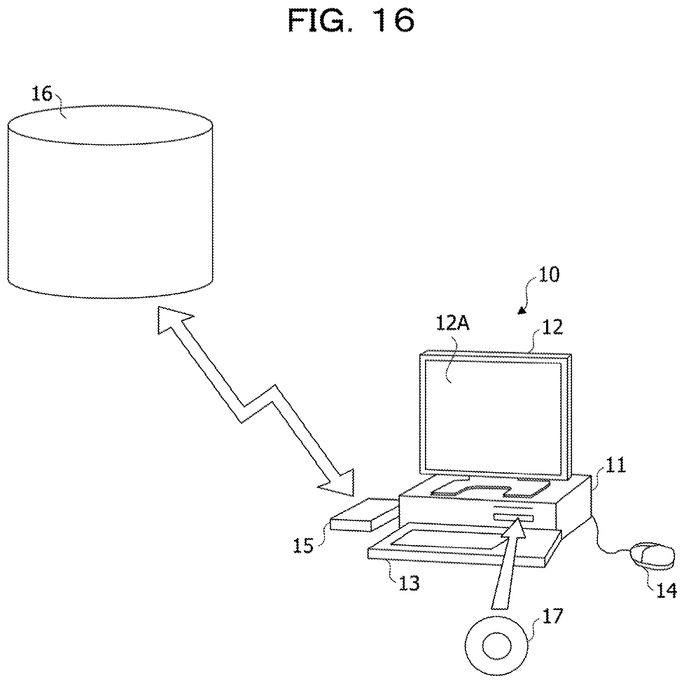

FIG. 16 is an example perspective view of a computer system to which the processing apparatus 220 is applied. A computer system 10 illustrated in FIG. 16 includes a main body 11, a display 12, a keyboard 13, a mouse 14, and a modem 15.

The main body 11 includes a central processing unit (CPU), a hard disk drive (HDD), a disk drive, and the like. The display 12 displays an analysis result and the like on a screen 12A according to an instruction from the main body 11. For example, a liquid crystal monitor is preferably used as the display 12. The keyboard 13 is an input part for inputting various information to the computer system 10. The mouse 14 is an input part for specifying an arbitrary position on the screen 12A of the display 12. The modem 15 accesses an external database or the like to download a program or the like stored in another computer system.

A program for causing the computer system 10 to have a function as the processing apparatus 220 is stored in a portable recording medium such as a disk 17. Alternatively, the program is downloaded from a recording medium 16 of another computer system by use of a communication device such as the modem 15, and is input to the computer system 10 to be compiled.

The program for causing the computer system 10 to have a function as the processing apparatus 220 causes the computer system 10 to operate as the processing apparatus 220. For example, the program may be stored in a computer-readable recording medium such as the disk 17. The computer-readable recording medium is not limited to the disk 17, an IC card memory, a magnetic disk such as a floppy (registered trademark) disk, a magneto-optical disk, a CD-ROM, a universal serial bus (USB) memory, or any other portable recording medium. The computer-readable recording media include various recording media accessible to the computer system connected via a communication device such as the modem 15 or a LAN.

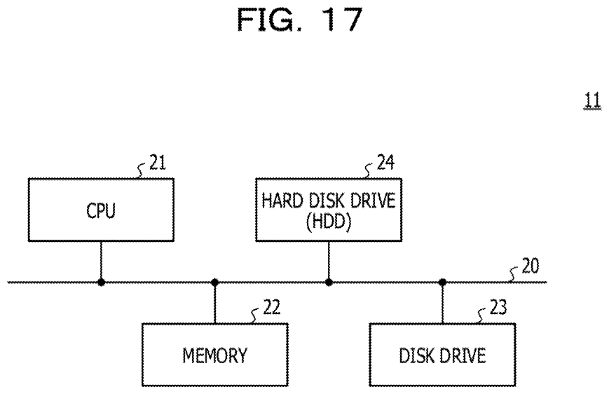

FIG. 17 is an example block diagram for describing the configuration of main parts in the main body 11 of the computer system 10. The main body 11 includes a CPU 21, a memory 22 including a RAM, a ROM, or the like, a disk drive 23 for the disk 17, and a hard disk drive (HDD) 24, which are connected by a bus 20. In the embodiment, the display 12, the keyboard 13, and the mouse 14 are connected to the CPU 21 via the bus 20. However, the display 12, the keyboard 13, and the mouse 14 may be directly connected to the CPU 21. In addition, the display 12 may also be connected to the CPU 21 via a known graphic interface (not illustrated) that processes input/output image data.

The keyboard 13 and the mouse 14 are input parts of the processing apparatus 220 in the computer system 10. The display 12 is a display part that displays, on the screen 12A, details of an input to the processing apparatus 220, or the like.

The computer system 10 is not limited to a computer system with the configuration illustrated in FIGS. 16 and 17. Various well-known elements may be added or may be used as alternatives.

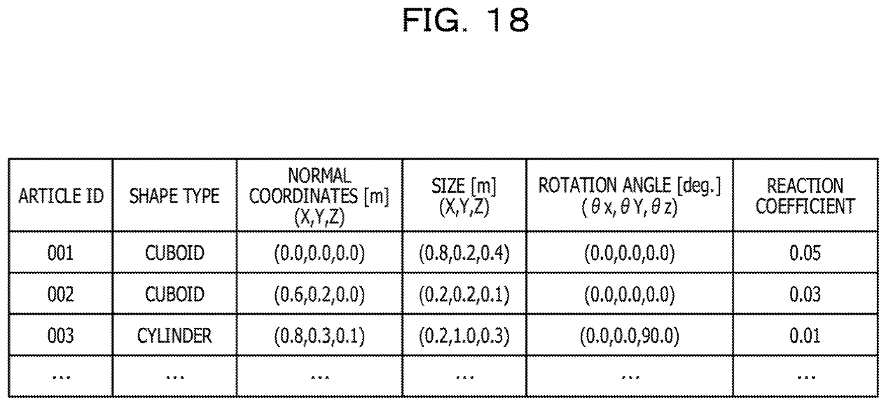

FIG. 18 is an example diagram illustrating article data.

The article data are data representing the coordinates and shape of an article to be displayed on the screen 210A. The article data includes an article ID, a shape type, normal coordinates, size, a rotation angle, and a reaction coefficient k.

The shape type indicates the outer shape of the article. The shape types “cuboid” and “cylinder” are given as examples in FIG. 18.

The normal coordinates indicate coordinate values of a reference point for coordinates representing the entire article. The unit of coordinate value is meter (m). An XYZ coordinate system is used as a coordinate system.

The size represents the lengths of the article in the X-axis direction, the Y-axis direction, and the Z-axis direction. The unit of size is meter (m). As an example, the lengths in the X-axis direction, the Y-axis direction, and the Z-axis direction represent a longitudinal length, a height, and a depth (length in the transverse direction), respectively.

The rotation angle is represented by rotation angles θx, θy, and θz with respect to the X-axis direction, the Y-axis direction, and the Z-axis direction, respectively. The unit of rotation angle is degree (deg.). The rotation angle θx is the angle of rotation of the article around the X-axis. Similarly, the rotation angles θy and θz are the angles of rotation of the article around the Y-axis and the Z-axis, respectively. The positive directions of the rotation angles θx, θy, and θz are preferably determined in advance.

The reaction coefficient k is the hardness of an article in the real space corresponding to the article to be displayed on the screen 210A. The reaction coefficient is a coefficient that increases as the article in the real space gets harder. The unit of reaction coefficient is N/mm. Another physical quantity such as Young's modulus may be used as the reaction coefficient k. As an example, the reaction coefficients k of articles with article IDs of 001, 002, and 003 have been set to 0.05, 0.03, and 0.01, respectively. For example, the article with the article ID of 001 is made of metal. The article with the article ID of 002 is made of resin. The article with the article ID of 003 is made of rubber.

The reaction force F is represented by equation (8) below. The reaction force F is obtained as a result of multiplying the reaction coefficient k by an intrusion amount ΔL and a normal vector n. The reaction force F is represented by a vector.

[Math 8]

\vec{F}=kΔL\vec{n} (8)

In equation (8), ΔL stands for an amount (intrusion amount) by which the pointer 230A has intruded into an article displayed on the screen 210A. The intrusion amount refers to an amount by which the pointer 230A has intruded into the article from a point where the pointer 230A has come into contact with the article.

The vector n is a normal vector of a point at which the pointer 230A has come into contact with the article displayed on the screen 210A. The vector of the reaction force F is obtained as a result of multiplying the reaction coefficient k by the normal vector n, as illustrated in equation (8). Use of the article data illustrated in FIG. 18 clarifies the direction of a surface brought into contact with the pointer 230A. Thus, it is possible to derive the normal vector n of the article displayed on the screen 210A from the article data.

Use of such article data enables an image specified by the article data to be displayed as with an image of an article displayed based on CAD data.

The article data are stored in the data holding part 224 of the processing apparatus 220.

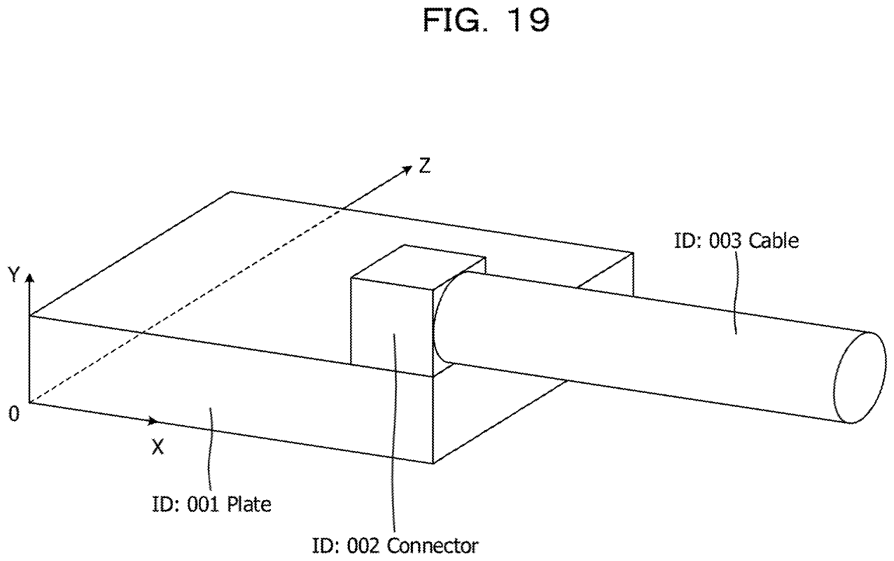

FIG. 19 is a diagram illustrating an example of images of articles.

FIG. 19 illustrates three articles represented by the article data of FIG. 18.

Article data of the article with the article ID of 001 include a shape type of cuboid, normal coordinates (X, Y, Z) of (0.0, 0.0, 0.0), size of (0.8, 0.2, 0.4), and rotation angles θx, θy, and θz of (0.0, 0.0, 0.0).

Since the normal coordinates (X, Y, Z) are (0.0, 0.0, 0.0), one of the vertices of the article with the article ID of 001 coincides with the origin O of the XYZ coordinate system.

Article data of the article with the article ID of 002 include a shape type of cuboid, normal coordinates (X, Y, Z) of (0.6, 0.2, 0.0), size of (0.2, 0.2, 0.1), and rotation angles θx, θy, and θz of (0.0, 0.0, 0.0).

Thus, the article with the article ID of 002 has been disposed on the article with the article ID of 001.

Article data of the article with the article ID of 003 Include a shape type of cylinder, normal coordinates (X, Y, Z) of (0.8, 0.3, 0.1), size of (0.2, 1.0, 0.3), and rotation angles θx, θy, and θz of (0.0, 0.0, 90.0).

Thus, the article with the article ID of 003 has been connected to a side surface of the article with the article ID of 002 after being rotated by 90 degrees around the Z-axis, the side surface facing the X-axis positive direction.

In the embodiment, the coordinates and shape of an article in an image projected on the screen 210A are specified by use of article data including an article ID, a shape type, normal coordinates, size, and a rotation angle illustrated in FIG. 18, as described above.

For example, in the case where the shape type of an article is cuboid, it is possible to find the coordinates of eight vertices by adding or subtracting, to or from normal coordinates, the lengths of the article in the X-axis direction, the Y-axis direction, and the Z-axis direction represented as the size. The coordinates of the eight vertices represent the coordinates of corners of the article having a shape type of cuboid.

If the coordinates of the eight vertices are found, it is possible to find expressions representing twelve edges. The expressions representing the twelve edges are expressions representing the coordinates of edges of the article having a shape type of cuboid.

In addition, if the coordinates of the eight vertices and/or the expressions representing the twelve edges are found, it is possible to find expressions representing six surfaces of the article having a shape type of cuboid and thus possible to find the coordinates of the surfaces.

In the case where the shape type of an article is cylinder, it is possible to find expressions representing circles (or ellipses) at both ends of the cylinder, based on the lengths of the article in the X-axis direction, the Y-axis direction, and the Z-axis direction represented as the size. In addition, it is possible to find expressions representing the coordinates of the circles (or ellipses) at both ends by using the expressions representing the circles (or ellipses) at both ends and normal coordinates. It is possible to find the coordinates of the side surface of the cylinder by using the expressions representing the coordinates of the circles (or ellipses) at both ends.

Articles having shape types of cuboid and cylinder have been described here. However, it is also possible to similarly find the coordinates and shapes of articles in various shapes, such as a sphere, a triangular pyramid, and a cuboid with a recess, in images projected on the screen 210A.

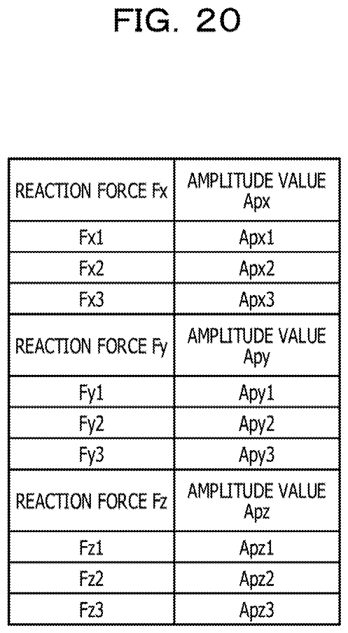

FIG. 20 is an example diagram illustrating tabular data in which the reaction forces F have been associated with amplitude values.

The vector of the reaction force F is represented by X, Y, and Z components (Fx, Fy, Fz). An amplitude value is represented by X, Y, and Z components (Apx, Apy, Apz). The X, Y, and Z components (Fx, Fy, Fz) of the reaction force F are associated with the X, Y, and Z components (Apx, Apy, Apz) of the amplitude value, respectively.

Therefore, if values of the X, Y, and Z components (Fx, Fy, Fz) of the reaction force F are found, it is possible to find values of the X, Y, and Z components (Apx, Apy, Apz) of the amplitude value. For example, in the case where the X, Y, and Z components of the reaction force F are represented as (Fx1, Fy1, Fz1), the X, Y, and Z components of the amplitude value are represented as (Apx1, Apy1, Apz1).

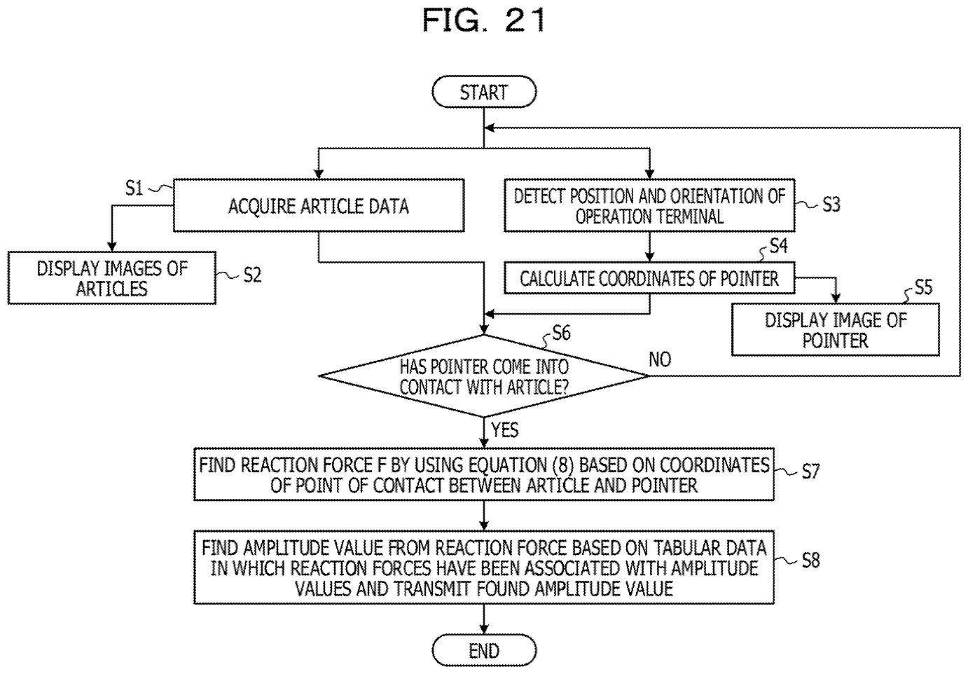

FIG. 21 is an example flowchart illustrating a process to be performed by the processing apparatus 220 according to the embodiment. As an example, the case of displaying images of the articles 211 and 212 on the screen 210A, as illustrated in FIG. 15, will be described here.

The processing apparatus 220 starts a process after the power is turned on (START).

The processing apparatus 220 acquires article data from the data holding part 224 (step S1).

The processing apparatus 220 generates video signals by using the article data, and causes the projection apparatus 2108 to project images (step S2). As a result, stereoscopic model images of the articles 211 and 212 are displayed on the screen 210A. The images of the articles 211 and 212 displayed on the screen 210A represent virtual objects existing in the virtual space.

The processes of steps S1 and S2 are performed by the video output part 223.

The processing apparatus 220 detects the position and orientation of the tactile sensation providing apparatus 100 in the real space (step S3). The process of step S3 is performed by the position detector 221.

The processing apparatus 220 detects the coordinates of the pointer 230A in the virtual space (step S4). The coordinates of the pointer 230A are detected by the position detector 221. Coordinate data of the pointer 230A are input to the contact determination part 222 and the video output part 223.

The processing apparatus 220 causes the projection apparatus 2108 to display the pointer 230A on the screen 210A based on the coordinates of the pointer 230A obtained in step S4 (step S5). A direction in which the pointer 230A is directed has been determined in advance in the tactile sensation providing apparatus 100. The pointer 230A is displayed at, for example, the intersection of the screen 210A and a straight line determined by the position of the tactile sensation providing apparatus 100 and the direction determined in advance.

As a result, the pointer 230A is displayed on the screen 210A displaying the stereoscopic images of the articles 211 and 212.

In step S5, it is possible to display tire pointer 230A by use of image data representing the pointer 230A. Data corresponding to the article data of the articles 211 and 212 are preferably prepared also for the pointer 230A such that a stereoscopic model image of the pointer 230A is displayed. However, in the case where it is possible to display the pointer 230A without using, for example, image data of the pointer 230A, there is no need for the data holding part 224 to hold the image data of the pointer 230A.

The process of step S5 is performed by the video output part 223. The processes of steps S3 to S5 are performed in parallel with the processes of steps S1 and S2.

The processing apparatus 220 determines whether the pointer 230A has come into contact with the article 211 or 212 (step S6). The process of step S6 is performed by the contact determination part 222. The contact determination part 222 determines whether the pointer 230A has come into contact with the article 211 or 212, based on the article data of the articles 211 and 212 and the coordinate data of the pointer 230A obtained in step S4.

It is possible to determine whether the pointer 230A has come into contact with the article 211 or 212, based on the existence or nonexistence of the intersection of a corner, an edge, or a surface represented by the article data of the article 211 or 212 and a position represented by the coordinate data of the pointer 230A.

Whether the pointer 230A has come into contact with the article 211 or 212 may also be determined based on whether a difference in position between the coordinate data of the pointer 230A and coordinates included in article data closest to the coordinate data is equal to or less than a predetermined value. For example, if performing determination in the following manner is preferable in terms of operability of the tactile sensation providing apparatus 100 in the simulation system 200, the tactile sensation providing apparatus 100 may be configured such that it is determined that contact has been made if the difference between the position included in the article data closest to the coordinate data and the position represented by the coordinate data is equal to or less than the predetermined value.

As an example, it is assumed that the pointer 230A has come into contact with the article 211 in step S7 to be described below. The same process is performed also in the case where the pointer 230A has come into contact with the article 212.

When it is determined that the pointer 230A has come into contact with the article 211 (S6: YES), the processing apparatus 220 finds a reaction force F by using equation (8) based on the coordinates of tire point of contact between the article 211 and the pointer 230A (step S7). The process of step S7 is performed by the contact determination part 222.

The contact determination part 222 finds an intrusion amount ΔL based on the coordinates of the pointer 230A and the article data of the article 211. In addition, the contact determination part 222 finds a normal vector n of the article 211 at the point of contact. Thus, the contact determination part 222 finds the vector of the reaction force F according to equation (8).

The drive controller 225 finds an amplitude value (Apx, Apy, Apz) from the reaction force F obtained in step S7, based on tabular data (see FIG. 20) in which reaction forces F have been associated with amplitude values.

Then, the drive controller 225 transmits the amplitude value (Apx, Apy, Apz) to the tactile sensation providing apparatus 100 (step S8). As a result, the vibrators 120-1, 120-2, and 120-3 of the tactile sensation providing apparatus 100 are driven.

This is the end of a series of processing steps (END). The process illustrated in FIG. 21 is repeatedly performed in a predetermined control cycle. Therefore, while the pointer 230A is in contact with an article displayed on the screen 210A, the vibrators 120-1, 120-2, and 120-3 are driven.

If it is determined in step S6 that both the articles 211 and 212 are out of contact with the pointer 230A (S6: NO), the flow returns to steps S1 and S3.

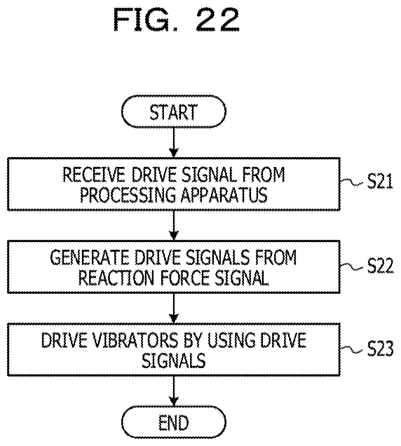

FIG. 22 is an example flowchart illustrating a process to be performed when the drive controller 140 of the tactile sensation providing apparatus 100 drives the vibrators 120-1, 120-2, and 120-3.

The drive controller 140 starts a process when the power to the tactile sensation providing apparatus 100 is turned on (START).

The drive controller 140 receives a drive signal from the processing apparatus 220 via the communication part 170 (step S21).

The drive controller 140 generates drive signals from a reaction force signal (step S22).

The drive controller 140 drives the vibrators 120-1, 120-2, and 120-3 by using the drive signals (step S23).

This is the end of a series of processing steps (END).

As described above, according to the simulation system 200 of the embodiment, when the pointer 230A operated by the tactile sensation providing apparatus 100 has come into contact with an article such as the article 211 or 212 in an image projected on the screen 210A, vibration patterns for vibrating the vibrators 120-1, 120-2, and 120-3 are changed in such a way as to provide a reaction force according to the Young's modulus of the article brought into contact with the pointer 230A.

Therefore, it is possible to provide a user with a tactile sensation representing the reaction force according to the Young's modulus of the article. This enables the user to recognize a touch on the article simply by a sense of the reaction force.

The simulation system 200 according to the embodiment uses the tactile sensation providing apparatus 100 to provide a user with a tactile sensation representing a reaction force according to the Young's modulus of an article brought into contact with the pointer 230A operated by the tactile sensation providing apparatus 100.

As Illustrated in FIG. 5, in the case where the user holds contact makers 111 and 112 with the thumb A and the forefinger B, the tactile sensation providing apparatus 100 causes the contact makers 111 and 112 to reciprocate in the Z-axis direction to achieve the sense that the thumb A is pressed in the Z-axis positive direction and the sense that the forefinger B is pressed in the Z-axis negative direction.

Therefore, according to the embodiment, it is possible to provide the tactile sensation providing apparatus 100 capable of providing the sense that the surface of skin is pulled.

A configuration has been described above in which the position and orientation of the tactile sensation providing apparatus 100 are detected by use of the marker 130 and the position measurement apparatus 240 (infrared cameras 240A and 240B). However, the position and orientation of the tactile sensation providing apparatus 100 may be detected by use of an infrared depth sensor, a magnetic sensor, a stereo camera, an acceleration sensor, or an angular velocity sensor, which does not need the marker 130, or any combination thereof.

A configuration has been described above in which the position of the marker 130 attached to the tactile sensation providing apparatus 100 is detected by the position measurement apparatus 240. However, for example, it is possible to use, as the position measurement apparatus 240, an apparatus that irradiates a subject with an infrared laser to calculate a distance (depth) to a point included in an image based on time that elapses before reflected light is received. If the position measurement apparatus 240 like that is used, it is possible to acquire an image of a user performing pointing operation onto the screen 210A and determine the position of the pointer 130A based on the user's posture, gesture, and/or the like, without attaching the marker 130 to the tactile sensation providing apparatus 100.

The tactile sensation providing apparatus and the simulation system according to an exemplary embodiment of the present embodiment have been described above. However, the present embodiment is not limited to the specifically disclosed embodiment, and various modifications and changes may be made to the embodiment without departing from the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A tactile sensation providing apparatus comprising:
a housing;
N (N is an integer equal to or greater than 2) vibrators attached to the housing, having resonance frequencies different from each other and configured to vibrate the housing; and
a drive controller configured to simultaneously drive the N vibrators with N drive signals that vibrate the N respective vibrators in a resonance state,
wherein the N drive signals cause the housing to generate reciprocating vibration by simultaneously driving the N respective vibrators, the reciprocating vibration having different speeds in a first direction and a second direction opposite to the first direction.

2. The tactile sensation providing apparatus according to claim 1, wherein
the N drive signals are represented by N terms of a Fourier series of sine waves,
one of the N drive signals that drives an i-th vibrator is represented as aᵢ sin[2π(if)t+{φᵢ+(i−1)π}], where i is any value from 1 to N and f is a resonance frequency of the i-th vibrator when i=1,
the i-th vibrator vibrates at a resonance frequency if while being driven by the drive signal that drives the i-th vibrator,
a predetermined phase φᵢ is a phase set for the drive signal that drives the i-th vibrator,
a predetermined coefficient aᵢ is an amplitude adjustment value set for the drive signal that drives the i-th vibrator, and
an acceleration to be generated to act on the housing when the drive signal is input to the i-th vibrator is determined such that the acceleration is represented as (A₁/i)sin[2π(if)t+{(i−1)π}], where A₁ is an acceleration amplitude of the housing to be generated when the drive signal is input to a first vibrator.

3. The tactile sensation providing apparatus according to claim 1, wherein
the N vibrators each include:
a spring;
a permanent magnet coupled to an end of the spring;
a damper coupled to the permanent magnet, in parallel with the spring; and
an electromagnetic coil configured to generate an electromagnetic force to attract the permanent magnet, and
the drive signals cause the N vibrators to resonate at the respective resonance frequencies, by causing the electromagnetic coils to switch between on and off.

4. A simulation system comprising:
a display configured to display an image of an article based on article data which represents a shape and coordinates of the article;
a tactile sensation providing apparatus configured to enable a user to manipulate a position of a pointer which is displayed on the display by moving the tactile sensation providing apparatus while holding the tactile sensation providing apparatus by the user; and
a processor configured to:
detect a position and an orientation of the tactile sensation providing apparatus;
detect coordinates of the pointer which is displayed on the display part, based on the position and the orientation detected by the first detector; and
determine whether the pointer comes into contact with the article which is displayed on the display, based on the coordinates included in the article data and the detected coordinates,
wherein the tactile sensation providing apparatus includes:
a housing;
N (N is an integer equal to or greater than 2) vibrators attached to the housing, having resonance frequencies different from each other and configured to vibrate the housing; and
a drive controller configured to simultaneously drive the N vibrators with N drive signals that vibrate the N respective vibrators in a resonance state, and
the N drive signals cause the housing to generate reciprocating vibration by simultaneously driving the N respective vibrators, the reciprocating vibration having different speeds in a first direction and a second direction opposite to the first direction.

5. The simulation system according to claim 4, wherein
the N drive signals are represented by N terms of a Fourier series of sine waves,
one of the N drive signals that drives an i-th vibrator is represented as aᵢ sin[2π(if)t+{φᵢ+(i−1)π}], where i is any value from 1 to N and f is a resonance frequency of the i-th vibrator when i=1,
the i-th vibrator vibrates at a resonance frequency if while being driven by the drive signal that drives the i-th vibrator,
a predetermined phase φᵢ is a phase set for the drive signal that drives the i-th vibrator,
a predetermined coefficient aᵢ is an amplitude adjustment value set for the drive signal that drives the I-th vibrator, and
an acceleration to be generated to act on the housing when the drive signal is input to the i-th vibrator is determined such that the acceleration is represented as (A₁/i)sin[2π(if)t+{(i−1)π}], where A₁ is an acceleration amplitude of the housing to be generated when the drive signal is input to a first vibrator.

6. The simulation system according to claim 4, wherein
the N vibrators each include:
a spring;
a permanent magnet coupled to an end of the spring;
a damper coupled to the permanent magnet, in parallel with the spring; and
an electromagnetic coil configured to generate an electromagnetic force to attract the permanent magnet, and
the drive signals cause the N vibrators to resonate at the respective resonance frequencies, by causing the electromagnetic coils to switch between on and off.
